(19) United States
(12) Patent Application Publication
(10) Pub. No.: US 2012/0286219 A1
(43) Pub. Date: Nov. 15, 2012

(54) SPUTTERING TARGET, SEMICONDUCTING COMPOUND FILM, SOLAR CELL COMPRISING SEMICONDUCTING COMPOUND FILM, AND METHOD OF PRODUCING SEMICONDUCTING COMPOUND FILM

(75) Inventors: Masakatsu Ikisawa, Ibaraki (JP); Hideo Takami, Ibaraki (JP); Tomoya Tamura, Ibaraki (JP)

(73) Assignee: JX NIPPON MINING & METALS CORPORATION, Tokyo (JP)

(21) Appl. No.: 13/519,208

(22) PCT Filed: Dec. 3, 2010
(86) PCT No.: PCT/JP2010/071660

§ 371 Date: Jul. 18, 2012

(30) Foreign Application Priority Data
Jan. 7, 2010 (JP) 2010-002057

(51) Int. Cl. C23C 14/34; H01B 1/22

(52) U.S. Cl. 252/514; 204/298.13; 252/512

(57) ABSTRACT

The present invention provides a sputtering target which comprises an alkali metal, a Ib group element, a IIIb group element, and a VIb group element, and has a chalcopyrite crystal structure. Provided is a sputtering target comprising Ib-IIIb-VIb group elements and having a chalcopyrite crystal structure, which is suitable for producing, via a single sputtering process, a light-absorbing layer comprising the Ib-IIIb-VIb group elements and having the chalcopyrite crystal structure.

### TECHNICAL FIELD

The present invention relates to a sputtering target, in particular to a sputtering target for producing a semiconducting compound film which is used as a light-absorbing layer of a thin-film solar cell, a method of producing such a target, a semiconducting compound film which is formed by using the foregoing sputtering target, a solar cell which comprises the foregoing semiconducting compound film as a light-absorbing layer, and a method of producing such a semiconducting compound film.

### BACKGROUND ART

In recent years, the mass production of Cu—In—Ga—Se (hereinafter indicated as “CIGS”)-based solar cells, which are highly efficient as thin-film solar cells, is advancing. As methods of producing the CIGS layer as the light-absorbing layer, known are the vapor deposition method and selenization.

The solar cells produced via the vapor deposition method are advantageous in that they yield high conversion efficiency, but they entail the following drawbacks; namely, low deposition rate, high cost, and low productivity.

On the other hand, while selenization is suitable for industrial mass production, selenization entails the following drawbacks; namely, it includes troublesome, complex and dangerous processes to form a CIGS film by preparing a laminated film of In and Cu—Ga, performing heat treatment in a hydrogen selenide atmosphere, and selenizing Cu, In, and Ga, and takes a lot of cost, work, and time.

Thus, in recent years, attempts have been made of using a CIGS-based sputtering target to prepare a CIGS-based light-absorbing layer via a single sputtering process. However, under the current circumstances, a suitable CIGS-based sputtering target has not yet been developed.

While it is possible to use a CIGS-based alloy sintered compact as a sputtering target and perform direct-current (DC) sputtering with a fast deposition rate and superior productivity, since the CIGS-based alloy sintered compact normally has a relatively high bulk resistance at several ten Ω or more, there are problems in that abnormal discharge such as arcing tends to occur, particles are generated on the film, and the film quality will consequently deteriorate.

Generally speaking, when an alkali metal such as sodium (Na) is added to the CIGS layer, it is known that the conversion efficiency of the solar cell will improve due to effects based on the increase in the crystal grain size, increase in the carrier concentration, and so on.

As conventionally known methods of supplying Na and the like, there are a method of supplying Na from Na-containing soda lime glass (Patent Document 1), a method of providing an alkali metal-containing layer on the back surface electrode via the wet process (Patent Document 2), a method of providing an alkali metal-containing layer on the precursor via the wet process (Patent Document 3), a method of providing an alkali metal-containing layer on the back surface electrode via the dry process (Patent Document 4), a method of adding an alkali metal at the time of forming the absorbing layer via the simultaneous vapor deposition method, or before or after the deposition (Patent Document 5).

Nevertheless, with the methods described in Patent Document 1 to Patent Document 3, the supply of the alkali metal from the alkali metal-containing layer to the CIGS layer is performed via thermal diffusion during the selenization of CuGa in all cases, and it is difficult to appropriately control the concentration distribution of the alkali metal in the CIGS layer.

This is because, when using Na-containing soda lime glass as the substrate, since the softening point is approximately 570° C., cracks tend to occur at a high temperature of 600° C. or higher and the temperature cannot be increased excessively. But if selenization is not performed at a high temperature of approximately 500° C. or higher, it becomes difficult to prepare a CIGS film with favorable crystallinity. In other words, the temperature controllable range during selenization is extremely narrow, and there is a problem in that it is difficult to control the appropriate diffusion of Na in the foregoing temperature range.

Moreover, with the methods described in Patent Document 4 and Patent Document 5, since the formed Na layer possesses moisture-absorption characteristics, the film quality may change during the atmospheric exposure after the deposition process, and the film will consequently peel. There is an additional problem in that the machinery costs are extremely high.

The foregoing problems are not unique to the CIGS system, and these problems are generally common in the production of solar cells which have a chalcopyrite crystal structure comprising Ib-IIIb-VIb group elements, and, for example, the same applies to those in which Cu is replaced with Ag, those in which the composition ratio of Ga and In is different, those in which a part of Se is replaced with S, and so on.

Moreover, there are Patent Documents which describe that sputtering is performed using a target when preparing an absorbing layer for use in a solar cell, and these Patent Documents describe as follows.

“Precipitation of the alkali metal compound is favorably performed via sputtering or vapor deposition. Used herein may be a target of alkali metal compound, or a mixture target of an alkali metal target and copper selenide CuₓSe_{y}, or a mixture target of an alkali metal target and indium selenide InₓSe_{y}. The metal-alkali metal mixed target, for instance, Cu/Na, Cu—Ga/Na or In/Na, may also be used.” (refer to paragraph [0027] of Patent Document 4 and Patent Document 6, respectively)

Nevertheless, the foregoing Patent Documents are referring to a target which is independently doped with an alkali metal before or during the production of the absorbing layer for use in a solar cell. So as long as the method where the target is independently doped with an alkali metal as described above is used, it is necessary to make adjustments with the other components on a case-by-case basis, and, if the respective targets having different components are not under sufficient management, there is a problem in that the components will fluctuate.

Moreover, Patent Document 7 discloses forming a light-absorbing layer of a solar cell by performing simultaneous vapor deposition of the alkali metal compound as the evaporation source, and the other elements (refer to paragraph [0019] and FIG. 1 of Patent Document 7). In the foregoing case, as with Patent Document 4 and Patent Document 6, there is a problem in that the components will fluctuate if the adjustment (component composition and vapor deposition conditions) with the other evaporants is insufficient.

Meanwhile, Non-Patent Document 1 discloses a method of producing a CIGS quaternary-system alloy sputtering target obtained by preparing powder based on a mechanical alloy to become the nanopowder raw material, and subsequently performing HIP (Hot Isostatic Pressing) treatment thereto, and additionally discloses the characteristics of such a target.

Nevertheless, Non-Patent Document 1 qualitatively describes about the characteristics of the CIGS quaternary-system alloy sputtering target obtained with the foregoing production method, of which density is high, but Non-Patent Document 1 fails to indicate any specific numerical values regarding the density.

While it can be assumed that the oxygen concentration is high since nanopowder is used, Non-Patent Document 1 also fails to provide any description regarding the oxygen concentration of the sintered compact, and further fails to provide any description regarding the bulk resistance which affects the sputtering characteristics. In addition, since expensive nanopowder is being used as the raw material, the target of Non-Patent Document 1 is inappropriate as a solar cell material which is demanded of low cost.

Moreover, Non-Patent Document 2 discloses a sintered compact having a composition of Cu(In_{0.8}Ga_{0.2})Se₂, density of 5.5 g/cm³, and relative density of 97%. Nevertheless, as the production method thereof, Non-Patent Document 2 merely describes that a uniquely-synthesized raw powder was subject to sintering via the hot press method, and a specific production method is not specified therein. In addition, Non-Patent Document 2 also fails to provide any description regarding the oxygen concentration and bulk resistance of the obtained sintered compact.

[Patent Document 1] Japanese Laid-Open Patent Publication No. 2004-47917

[Patent Document 2] Japanese Patent No. 3876440

[Patent Document 3] Japanese Laid-Open Patent Publication No. 2006-210424

[Patent Document 4] Japanese Patent No. 4022577

[Patent Document 5] Japanese Patent No. 3311873

[Patent Document 6] Japanese Laid-Open Patent Publication No. 2007-266626

[Patent Document 7] Japanese Laid-Open Patent Publication No. H8-102546

[Non-Patent Document 1] Thin Solid Films, 332(1998), P. 340 to 344

[Non-Patent Document 2] Electronic Materials, November 2009, P. 42 to 45

### SUMMARY OF INVENTION

### Technical Problem

In light of the foregoing circumstances, the present invention provides a sputtering target comprising Ib-IIIb-VIb group elements and having a chalcopyrite crystal structure which is suitable for producing, via a single sputtering process, a light-absorbing layer comprising Ib-IIIb-VIb group elements and having a chalcopyrite crystal structure. This sputtering target is characterized in that the generation of abnormal discharge can be inhibited since the target is of low resistance, and it is a high-density target. In addition, an object of the present invention is to provide: a layer, in which alkali metal concentration is controlled and which comprises the Ib-IIIb-VIb group elements and has a chalcopyrite crystal structure, formed by using the sputtering target which comprises the Ib-IIIb-VIb group elements and has a chalcopyrite crystal structure; and a method of producing the layer which comprises the Ib-IIIb-VIb group elements and has a chalcopyrite crystal structure; and a method of producing such a layer; as well as a solar cell in which a layer comprising the Ib-IIIb-VIb group elements and having a chalcopyrite crystal structure is used as its light-absorbing layer.

### Solution to Problem

As a result of intense study, the present inventors discovered that, by adding an alkali metal to a sputtering target which comprises Ib-IIIb-VIb group elements and has a chalcopyrite crystal structure, it is possible to dramatically reduce the bulk resistance, and inhibit the generation of abnormal discharge during the sputtering process. The present invention was devised based on the foregoing discovery.

In other words, the present invention provides:

1. A sputtering target comprising an alkali metal, a Ib group element, a IIIb group element and a VIb group element, and having a chalcopyrite crystal structure;

2. The sputtering target according to 1 above, wherein the alkali metal is at least one element selected from lithium (Li), sodium (Na) and potassium (K), the Ib group element is at least one element selected from copper (Cu) and silver (Ag), the IIIb group element is at least one element selected from aluminum (Al), gallium (Ga) and indium (In), and the VIb group element is at least one element selected from sulfur (S), selenium (Se) and tellurium (Te);

3. The sputtering target according to 2 above, wherein an atomic ratio of gallium (Ga) relative to a total amount of gallium (Ga) and indium (In), Ga/(Ga+In), is 0 to 0.4;

4. The sputtering target according to any one of 1 to 3 above, wherein an atomic ratio of all Ib group elements relative to all IIIb group elements, Ib/IIIb, is 0.6 to 1.1;

5. The sputtering target according to any one of 1 to 4 above, wherein a concentration of the alkali metal is 10¹⁶ to 10¹⁸ cm⁻³;

6. The sputtering target according to any one of 1 to 5 above, wherein a relative density is 90% or more; and

7. The sputtering target according to any one of 1 to 6 above, wherein a bulk resistance is 5 Ωcm or less.

Moreover, the present invention provides:

8. A semiconducting compound film comprising an alkali metal, a Ib group element, a IIIb group element and a VIb group element, and having a chalcopyrite crystal structure, wherein a variation in a concentration of the alkali metal in a film thickness direction is ±10% or less;

9. The semiconducting compound film according to 9 above, wherein the alkali metal is at least one element selected from lithium (Li), sodium (Na) and potassium (K), the Ib group element is at least one element selected from copper (Cu) and silver (Ag), the IIIb group element is at least one element selected from aluminum (Al), gallium (Ga) and indium (In), and the VIb group element is at least one element selected from sulfur (S), selenium (Se) and tellurium (Te);

10. The semiconducting compound film according to 9 above, wherein an atomic ratio of gallium (Ga) relative to a total amount of gallium (Ga) and indium (In), Ga/(Ga+In), is 0 to 0.4;

11. The semiconducting compound film according to any one of 8 to 10 above, wherein an atomic ratio of all Ib group elements relative to all IIIb group elements, Ib/IIIb, is 0.6 to 1.1; and

12. The semiconducting compound film according to any one of 8 to 11 above, wherein a concentration of the alkali metal is 10¹⁶ to 10¹⁸ cm⁻³.

The present invention additionally provides:

13. A solar cell in which the semiconducting compound film according to any one of 8 to 12 above is used as a light-absorbing layer;

14. A method of producing the sputtering target according to any one of 1 to 7 above, wherein at least one compound selected from Li₂O, Na₂O, K₂O, Li₂S, Na₂S, K₂S, Li₂Se, Na₂Se and K₂Se is used as a compound to be added as the alkali metal, and sintering is performed using the selected compound, the Ib group element, the IIIb group element and the VIb group element to produce a sputtering target having a chalcopyrite crystal structure; and

15. A method of producing a semiconducting compound film, wherein sputtering is performed using the sputtering target according to any one of 1 to 8 above to produce the semiconducting compound film according to any one of 9 to 14 above.

### Effects of Invention

As described above, the present invention yields superior effects of being able to reduce the bulk resistance and inhibit the generation of abnormal discharge during the sputtering process by adding an alkali metal to a sputtering target which comprises Ib-IIIb-VIb group elements and has a chalcopyrite crystal structure.

Moreover, since an alkali metal is contained in the sputtering target which comprises Ib-IIIb-VIb group elements and has a chalcopyrite crystal structure; it is possible to reduce excess processes and costs for separately providing an alkali metal-containing layer, an alkali metal diffusion blocking layer or the like, and the present invention yields an extremely significant effect of being able to control the concentration so that the alkali metal in the film becomes uniform.

### DESCRIPTION OF EMBODIMENTS

An alkali metal is also referred to as a la element of the periodic table, but in the present invention hydrogen is not included in the alkali metal. This is because it is difficult to effectively add hydrogen, and hydrogen is not acknowledged as being effective for expressing electrical and systematic properties.

It is considered that, as a result of adding an alkali metal, the alkali metal as a monovalent element is displaced to a trivalent lattice location and hole emission occurs, whereby the conductivity is improved.

Accordingly in order to achieve the foregoing effect, any element may be used so as long as it is an alkali metal, but Li, Na and K are desirably used from the perspective of availability and price of the compound. Moreover, since these metals have extremely strong reactivity as a single element and in particular cause dangers due to a severe reaction with water, it is desirable to adding the alkali metal in the form of a compound containing the foregoing elements.

Accordingly, Li₂O, Na₂O, K₂O, Li₂S, Na₂S, K₂S, Li₂Se, Na₂Se, K₂Se and the like which is accessible and relatively inexpensive are desirably used as a compound. In particular, a Se compound is desirably used since Se is a constituent element of CIGS, and there is no fear of generating a lattice defect or a different composition material.

A Ib group element includes Cu, Ag and Au as elements belonging to the Ib group of the periodic table, and is monovalent as an electron valence in the chalcopyrite crystal structure of CIGS or the like in the present invention. CIGS-based solar cells are produced the most as solar cells, but research and development of materials in which Cu is substituted with Ag are also being conducted, and the present invention is not limited to Cu, and can also be applied to other Ib group elements. However, since Au is expensive, Cu and Ag are desirable in terms of cost. Among the above, Cu is more preferably since it is even less expensive and yields favorable solar cell characteristics.

A IIIb group element is B, Al, Ga, In and TI as elements belonging to the IIIb group of the periodic table, and is trivalent as an electron valence in the chalcopyrite crystal structure of CIGS or the like in the present invention. Among the foregoing elements, since it is difficult to achieve a chalcopyrite crystal structure with B and B has inferior solar cell characteristics, and since TI is toxic and expensive; Al, Ga, and In are desirably used. In particular, Ga and In are more preferably used since an appropriate bandgap can be easily adjusted depending on the composition.

A VIb group element is O, S, Se, Te and Po as elements belonging to the VIb group of the periodic table, and is hexavalent as an electron valence in the chalcopyrite crystal structure of CIGS or the like in the present invention. Among the foregoing elements, since it is difficult to achieve a chalcopyrite crystal structure with O and O has inferior solar cell characteristics, and since Po is a radioactive element and expensive; S, Se, and Te are desirably used. In particular, S and Se are more preferably used since an appropriate bandgap can be easily adjusted depending on the composition. Moreover, it is also possible to use only Se.

Ga/(Ga+In) as the atomic ratio of Ga relative to the total amount of Ga and In is correlated to the bandgap and composition; and if this ratio becomes large, the Ga element will increase, and thereby cause the bandgap to increase. This ratio is desirably within the range of 0 to 0.4 in order to obtain the appropriate bandgap as a solar cell.

This is because, if this ratio becomes larger than the foregoing range, the bandgap will become too wide and the number of electrons that are excited by the absorbed solar light will decrease, and consequently deteriorating the conversion efficiency of the solar cell. Moreover, due to the appearance of a heterophase, the density of the sintered compact will decrease. The range of the foregoing ratio should be 0.1 to 0.3 to achieve more preferable bandgap in relation to the solar spectrum.

Ib/IIIb as the ratio of the total atomicity of the Ib group elements relative to the total atomicity of the IIIb group elements is correlated to the conductivity and composition, and is desirably 0.6 to 1.1. If this ratio is too large, the Cu—Se compound becomes precipitated and the density of the sintered compact will decrease. If this ratio is too small, the conductivity will deteriorate. A more desirable range of the foregoing ratio is 0.8 to 1.0.

Concentration of the alkali metal is correlated to the conductivity and crystallinity, and is desirably 10¹⁶ to 10¹⁸ cm⁻³. If the concentration is lower than the foregoing range, sufficient conductivity cannot be obtained, and the effect of adding the alkali metal becomes insufficient. In addition, since the bulk resistance will be high, this causes adverse effects such as the generation of abnormal discharge during the sputtering process and adhesion of particles on the film.

Meanwhile, if the concentration is higher than the foregoing range, the sintered compact density will decrease. The alkali metal concentration can be analyzed using various analytical methods. For instance, the alkali metal concentration in the sintered compact can be evaluated via ICP analysis or other methods, and the alkali metal concentration in the film and the distribution thereof in the film thickness direction can be via SIMS analysis or other methods.

The target of the present invention can achieve a relative density of 90% or more, preferably 95% or more, and more preferably 96% or more. The relative density expresses the density of the respective targets as a ratio when the true density of the sintered compact of the respective compositions is 100. The density of the target can be measured via the Archimedean method.

If the relative density is low, protrusive shapes referred to as nodules tend to be formed on the target surface when sputtering is performed for a long time, and there are problems in that the generation of abnormal discharge and generation of particles on the film occur with such nodules as the base point. These problems contribute to the deterioration in the conversion efficiency of the CIGS solar cells. The high-density target of the present invention can easily avoid the foregoing problems.

The bulk resistance of the target of the present invention can be caused to be 5 Ωm or less, and preferably 4 Ωm or less. This effect is a result of holes being formed as a result of adding an alkali metal. If the bulk resistance is high, it tends to cause the generation of abnormal discharge during the sputtering process.

Variation in the concentration of the alkali metal in the film thickness direction of the film of the present invention is ±10% or less, and preferably 6% or less. When, as conventionally, an alkali metal such as Na is supplied from a glass substrate or an alkali metal-containing layer via diffusion; the alkali metal concentration at the portion near the alkali metal source is extremely high, but the concentration drastically decreases with increasing distance from the source, and the difference in concentration of the alkali metal in the film will increase to an incommensurable level. However, in the case of the present invention, since the film is obtained by performing sputtering with the use of a target of high uniformity containing an alkali metal, the present invention yields a superior effect in that the concentration of the alkali metal in the film will also possess high uniformity even in the film thickness direction.

The sputtering target, the semiconducting compound film, and the solar cell comprising the foregoing semiconducting compound film as a light-absorbing layer can be prepared, for instance, as follows.

The respective raw materials are weighed to achieve a predetermined composition ratio and concentration, and sealed in a quartz ampule; the inside of the quartz ampule is vacuumed; and the suction opening is thereafter sealed to keep the inside of the quartz ampule in a vacuum state. This is in order to inhibit the reaction with oxygen, and internally confine the gaseous substance caused by the reaction between the raw materials.

Subsequently, the quartz ampule is set in a heating furnace and the temperature thereof is increased according to a predetermined temperature increase program. What is important here is that the rate of temperature increase is set to be slow near the temperature of reaction between the raw materials so as to prevent damage to the quartz ampule due to the drastic reaction, and reliably produce the compound composition of predetermined compositions.

As a result of sieving the synthetic raw material obtained as described above, a synthetic raw powder of a predetermined grain size or less is selected. Hot press (HP) is thereafter performed to obtain a sintered compact. What is important here is that an appropriate temperature below the melting point of the respective compositions is used, and sufficient pressure is applied. It is thereby possible to obtain a high-density sintered compact.

The sintered compact obtained as described above is processed into an appropriate thickness and shape to obtain a sputtering target. As a result of setting argon gas or the like to a predetermined pressure and sputtering the target obtained as described above, it is possible to obtain a thin film having a composition that is basically the same as the target composition. Concentration of the alkali metal in the film can be measured via SIMS or other analytical methods.

Since the semiconducting compound film as the light-absorbing layer of a solar cell can be prepared as described above, the remaining constituent elements of a solar cell can be prepared using conventional methods. In other words, a solar cell can be prepared by sputtering a molybdenum electrode on a glass substrate, thereafter forming the semiconducting compound film of the present invention, subjecting CdS to chemical bath deposition, and forming ZnO as the buffer layer or aluminum-doped ZnO as the transparent conductive film.

### EXAMPLES

The Examples and Comparative Examples of the present invention are now explained. Note that the ensuing Examples are merely representative illustrations, and there is no need for the present invention to be limited to these Examples. The present invention should be interpreted within the range of the technical concept described in the specification.

### Example 1

Cu, In, Ga, Se and Na₂Se as the raw materials were weighed to achieve: Ga/(Ga+In)=0.2 as the atomic ratio of Ga and In; Cu/(Ga+In)=1.0 as the atomic ratio of Cu as a Ib element relative to the total amount of Ga and In as IIIb elements; and a Na concentration of 10¹⁷ cm⁻³.

Subsequently, these raw materials were placed in a quartz ampule, the inside of the quartz ampule was vacuumed and thereafter sealed, and the quartz ampule was subsequently set in a heating furnace to synthesize the raw materials. The temperature increase program was set so that the rate of temperature increase from room temperature to 100° C. is 5° C./min, the subsequent rate of temperature increase up to 400° C. is 1° C./min, the subsequent rate of temperature increase up to 550° C. is 5° C./min, and the subsequent rate of temperature increase up to 650° C. is 1.66° C./min. The quartz ampule was thereafter retained for 8 hours at 650° C., and subsequently cooled in the heating furnace for 12 hours until reaching room temperature.

After passing the Na-containing CIGS synthetic raw powder obtained as described above through a sieve of 120 mesh, hot press (HP) was performed. The HP conditions were as follows; namely, the rate of temperature increase from room temperature to 750° C. was set to 10° C./min, the temperature was maintained at 750° C. for 3 hours, heating was thereafter stopped, and the raw material was subsequently naturally cooled in the furnace.

30 minutes after reaching the temperature of 750° C., pressure of 200 kgf/cm² was applied for 2 hours and 30 minutes, and the application of pressure was stopped simultaneously with the end of heating.

The relative density of the obtained CIGS sintered compact was 96.0%, and the bulk resistance was 3.5 Ωcm. This sintered compact was processed into a disk shape having a diameter of 6 inches and a thickness of 6 mm to obtain a sputtering target.

Subsequently, this target was subject to sputtering. The sputter power was 1000 W for direct current (DC), atmosphere gas was argon, gas flow rate was 50 sccm, and sputtering pressure was 0.5 Pa.

The Na concentration in the Na-containing CIGS film having a film thickness of approximately 1 μm was analyzed via SIMS. The Na concentration variation obtained by (“maximum concentration”−“minimum concentration”)/((“maximum concentration”+“minimum concentration”)/2)×100% was 5.3%. The foregoing results are shown in Table 1. As evident from the above, the results showed favorable values capable of achieving the object of the present invention.

TABLE 1

| | | | | Alkali | Relative | Bulk | Variation in |
|---|---|---|---|---|---|---|---|
| | Ga/(Ga + In) | Ib/IIIb | Alkali Metal | Concentration | Density | Resistance | Alkali Metal |
| | Ratio | Ratio | Compound | (cm⁻³) | (%) | (Ωcm) | Concentration (%) |
| Example 1 | 0.2 | 1.0 | Na₂Se | 10 ¹⁷ | 96.0 | 3.5 | 5.3 |
| Example 2 | 0.4 | 1.0 | Na₂Se | 10 ¹⁷ | 95.3 | 3.1 | 5.9 |
| Example 3 | 0.0 | 1.0 | Na₂Se | 10 ¹⁷ | 95.4 | 3.3 | 5.7 |
| Example 4 | 0.2 | 0.8 | Na₂Se | 10 ¹⁷ | 94.8 | 3.2 | 5.5 |
| Example 5 | 0.2 | 0.6 | Na₂Se | 10 ¹⁷ | 93.5 | 3.1 | 5.6 |
| Example 6 | 0.2 | 1.0 | Na₂O | 10 ¹⁷ | 96.5 | 3.9 | 5.5 |
| Example 7 | 0.2 | 1.0 | Na₂S | 10 ¹⁷ | 95.8 | 3.7 | 5.4 |
| Example 8 | 0.2 | 1.0 | Li₂Se | 10 ¹⁷ | 93.7 | 3.8 | 5.7 |
| Example 9 | 0.2 | 1.0 | K₂Se | 10 ¹⁷ | 93.6 | 3.7 | 5.6 |
| Example 10 | 0.2 | 1.0 | Na₂Se | 2 × 10 ¹⁶ | 93.2 | 4.7 | 4.3 |
| Example 11 | 0.2 | 1.0 | Na₂Se | 8 × 10 ¹⁷ | 96.6 | 2.1 | 8.9 |
| Comparative | 0.5 | 1.0 | Na₂Se | 10 ¹⁷ | 87.3 | 4.1 | 5.8 |
| Example 1 | | | | | | | |
| Comparative | 0.2 | 0.4 | Na₂Se | 10 ¹⁷ | 85.6 | 131.3 | 5.9 |
| Example 2 | | | | | | | |
| Comparative | 0.2 | 1.3 | Na₂Se | 10 ¹⁷ | 83.7 | 67.0 | 5.8 |
| Example 3 | | | | | | | |
| Comparative | 0.2 | 1.0 | Na₂Se | 10 ¹⁵ | 93.5 | 323.2 | 3.3 |
| Example 4 | | | | | | | |
| Comparative | 0.2 | 1.0 | Na₂Se | 10 ¹⁹ | 84.9 | 1.7 | 9.5 |
| Example 5 | | | | | | | |

### Examples 2 and 3

Other than that the atomic ratio of Ga and In was Ga/(Ga+In)=0.4 in Example 2 and Ga/(Ga+In)=0.0 in Example 3; a sintered compact and a thin film were prepared under the same conditions as Example 1 in each case. The results of the characteristics of the sintered compacts and the thin films are also shown in Table 1.

In Example 2, the relative density was 95.3%, the bulk resistance value was 3.1 Ωcm, and the alkali concentration variation was 5.9%. In Example 3, the relative density was 95.4%, the bulk resistance value was 3.3 Ωcm, and the variation in alkali metal concentration was 5.7%. As shown in Table 1, the results in both cases showed favorable values capable of achieving the object of the present invention.

### Examples 4 and 5

Other than that the atomic ratio of Cu as a Ib element relative to the total amount of Ga and In as IIIb elements was Cu/(Ga+In)=0.8 and Cu/(Ga+In)=0.6 respectively; a sintered compact and a thin film were prepared under the same conditions as Example 1 in each case. The results of the characteristics of the sintered compacts and the thin films are also shown in Table 1.

In Example 4, the relative density was 94.8%, the bulk resistance value was 3.2 Ωcm, and the alkali concentration variation was 5.5%. In Example 5, the relative density was 93.5%, the bulk resistance value was 3.1 Ωcm, and the variation in alkali metal concentration was 5.6%. As shown in Table 1, the results in both cases showed favorable values capable of achieving the object of the present invention.

### Examples 6 to 9

Other than using, as the compound upon adding an alkali metal, Na₂O in Example 6, Na₂S in Example 7, Li₂Se in Example 8, and K₂Se in Example 9 as respectively indicated in Table 1; a sintered compact and a thin film were prepared under the same conditions as Example 1 in each case. The results of the characteristics of the sintered compacts and the thin films are also shown in Table 1.

In Example 6, the relative density was 96.5%, the bulk resistance value was 3.9 Ωcm, and the alkali concentration variation was 5.5%. In Example 7, the relative density was 95.8%, the bulk resistance value was 3.7 Ωcm, and the variation in alkali metal concentration was 5.4%. In Example 8, the relative density was 93.7%, the bulk resistance value was 3.8 Ωcm, the alkali concentration variation was 5.7%. In Example 9, the relative density was 93.6%, the bulk resistance value was 3.7 Ωcm, and the variation in alkali metal concentration was 5.6%. As shown in Table 1, the results in all cases showed favorable values capable of achieving the object of the present invention.

### Examples 10 and 11

Other than that the alkali metal concentration was 2×10¹⁶ cm⁻³ in Example 10 and 8×10¹⁶ cm⁻³ in Example 11 as indicated in Table 1; a sintered compact and a thin film were prepared under the same conditions as Example 1 in each case. The results of the characteristics of the sintered compacts and the thin films are also shown in Table 1.

In Example 9, the relative density was 93.2%, the bulk resistance value was 4.7 Ωcm, and the alkali concentration variation was 4.3%. In Example 10, the relative density was 96.6%, the bulk resistance value was 2.1 Ωcm, and the variation in alkali metal concentration was 8.9%. As shown in Table 1, the results in both cases showed favorable values capable of achieving the object of the present invention.

### Comparative Example 1

Other than that the atomic ratio of Ga and In was Ga/(Ga+In)=0.5; a sintered compact and a thin film were prepared under the same conditions as Example 1. This is a case where the atomicity of Ga exceeds the conditions of the present invention. The results of the characteristics of the sintered compact and the thin film are also shown in Table 1.

As shown in Table 1, in Comparative Example 1, the relative density was 87.3%, the bulk resistance value was 4.1 Ωcm, and the variation in alkali metal concentration was 5.8%. The bulk resistance value and variation in alkali metal concentration were not a particular problem in Comparative Example 1, but the relative density was low. The results were undesirable if aiming the density to improve.

### Comparative Examples 2 and 3

Other than that the atomic ratio of Cu as a Ib element relative to the total amount of Ga and In as IIIb elements was Cu/(Ga+In)=0.4 in Comparative Example 2 and Cu/(Ga+In)=1.3 in Comparative Example 3; a sintered compact and a thin film were prepared under the same conditions as Example 1 in each case. Cu/(Ga+In) was lower than the conditions of the present invention in Comparative Example 2, and Cu/(Ga+In) exceeded the conditions of the present invention in Comparative Example 3. The results of the characteristics of the sintered compacts and the thin films are also shown in Table 1.

As shown in Table 1, in Comparative Example 2, the relative density was 85.6%, the bulk resistance value was 131.3 Ωcm, and the variation in alkali metal concentration was 5.9%; and in Comparative Example 3, the relative density was 83.7%, the bulk resistance value was 67.0 Ωcm, and the alkali concentration variation was 5.8%. The variation in alkali metal concentration was not a major problem, but the relative density was low and the bulk resistance value was considerably high. The results were inferior.

### Comparative Examples 4 and 5

Other than that the alkali metal concentration was 1×10¹⁵ cm⁻³ in Comparative Example 4 and 1×10¹⁹ cm⁻³ in Comparative Example 5 as indicated in Table 1; a sintered compact and a thin film were prepared under the same conditions as Example 1 in each case. The alkali metal concentration was too low in Comparative Example 4, and the alkali metal concentration was too high in Comparative Example 5. Both cases fail to satisfy the conditions of the present invention. The results of the characteristics of the sintered compacts and the thin films are also shown in Table 1.

As shown in Table 1, in Comparative Example 4, the relative density was 93.5%, the bulk resistance value was 323.2 Ωcm, and the variation in alkali metal concentration was 3.3%; and in Comparative Example 5, the relative density was 84.9%, the bulk resistance value was 1.7 Ωcm, and the variation in alkali metal concentration was 9.5%.

In Comparative Example 4, the relative density and variation in alkali metal concentration were not problematic, but the bulk resistance value was considerably high, and the results were inferior. In Comparative Example 5, the bulk resistance value is not problematic, but the relative density is low, and there was a problem in that the variation in alkali metal concentration increases.

### INDUSTRIAL APPLICABILITY

As described above, the present invention yields superior effects of being able to reduce the bulk resistance and inhibit the generation of abnormal discharge during the sputtering process by adding an alkali metal to a sputtering target which comprises Ib-IIIb-VIb group elements and has a chalcopyrite crystal structure. Moreover, since an alkali metal is to be contained in the sputtering target which comprises Ib-IIIb-VIb group elements and has a chalcopyrite crystal structure; it becomes possible to reduce excess processes and costs for separately providing an alkali metal-containing layer, an alkali metal diffusion blocking layer or the like, and the present invention yields an extremely significant effect of being able to control the concentration so that the alkali metal in the film becomes uniform.

Accordingly, the present invention is useful as a light-absorbing layer material of a thin-film solar cell, and is particularly useful as a material of an alloy thin film having high conversion efficiency.

1. A sputtering target comprising an alkali metal, a Ib group element, a IIIb group element and a VIb group element, and having a chalcopyrite crystal structure.

2. The sputtering target according to claim 1, where the alkali metal is at least one element selected from lithium (Li), sodium (Na) and potassium (K), the Ib group element is at least one element selected from copper (Cu) and silver (Ag), the IIIb group element is at least one element selected from aluminum (Al), gallium (Ga) and indium (In), and the VIb group element is at least one element selected from sulfur (S), selenium (Se) and tellurium (Te).

3. The sputtering target according to claim 2, wherein an atomic ratio of gallium (Ga) relative to a total amount of gallium (Ga) and indium (In), Ga/(Ga+In), is 0 to 0.4.

4. The sputtering target according to claim 3, wherein an atomic ratio of all Ib group elements relative to all IIIb group elements, Ib/IIIb, is 0.6 to 1.1.

5. The sputtering target according to claim 4, wherein a concentration of the alkali metal is 10¹⁶ to 10¹⁸ cm⁻³.

6. The sputtering target according to claim 5, wherein a relative density is 90% or more.

7. The sputtering target according to claim 6, wherein a bulk resistance is 5 Ωcm or less.

8. A semiconducting compound film formed by sputtering through use of the sputtering target according to claim 1, comprising an alkali metal, a Ib group element, a IIIb group element and a VIb group element, and having a chalcopyrite crystal structure, wherein a variation in a concentration of the alkali metal in a film thickness direction is ±10% or less.

9. The semiconducting compound film according to claim 8, wherein the alkali metal is at least one element selected from lithium (Li), sodium (Na) and potassium (K), the Ib group element is at least one element selected from copper (Cu) and silver (Ag), the IIIb group element is at least one element selected from aluminum (Al), gallium (Ga) and indium (In), and the VIb group element is at least one element selected from sulfur (S), selenium (Se) and tellurium (Te).

10. The semiconducting compound film according to claim 9, wherein an atomic ratio of gallium (Ga) relative to a total amount of gallium (Ga) and indium (In), Ga/(Ga+In), is 0 to 0.4.

11. The semiconducting compound film according to claim 10, wherein an atomic ratio of all Ib group elements relative to all IIIb group elements, Ib/IIIb, is 0.6 to 1.1.

12. The semiconducting compound film according to claim 11, wherein a concentration of the alkali metal is 10¹⁶ to 10¹⁸ cm⁻³.

13. (canceled)

14. A method of producing the sputtering target according to claim 1, wherein at least one compound selected from Li₂O, Na₂O, K₂O, Li₂S, Na₂S, K₂S, Li₂Se, Na₂Se and K₂Se is used as a compound to be added as the alkali metal, and sintering is performed using the selected compound, the Ib group element, the IIIb group element and the VIb group element to produce a sputtering target having a chalcopyrite crystal structure.

15. (canceled)

16. The semiconducting compound film according to claim 8, wherein an atomic ratio of all Ib group elements relative to all IIIb group elements, Ib/IIIb, is 0.6 to 1.1.

17. The semiconducting compound film according to claim 8, wherein a concentration of the alkali metal is 10¹⁶ to 10¹⁸ cm⁻³.

18. The sputtering target according to claim 1, wherein an atomic ratio of all Ib group elements relative to all IIIb group elements, Ib/IIIb, is 0.6 to 1.1.

19. The sputtering target according to claim 1, wherein a concentration of the alkali metal is 10¹⁶ to 10¹⁸ cm⁻³.

20. The sputtering target according to claim 1, wherein a relative density is 90% or more.

21. The sputtering target according to claim 1, wherein a bulk resistance is 5 Ωcm or less.
